(19) United States
(12) Patent Application Publication
(10) Pub. No.: US 2026/0236051 A1
(43) Pub. Date: Aug. 13, 2026

(54) Multiple Voltage Support for RF Circuits

(71) Applicant: pSemi Corporation, San Diego, CA (US)

(72) Inventors: Merlin GREEN, San Diego, CA (US); Parvez H. DARUWALLA, San Diego, CA (US); Khushali SHAH, Newark, CA (US); Miles SANNER, San Diego, CA (US)

(21) Appl. No.: 19/049,862

(22) Filed: Feb. 10, 2025

(51) Int. Cl. G05F 1/575; G05F 1/569; H03F 3/24

(52) U.S. Cl. CPC G05F 1/575; G05F 1/569; H03F 3/245; H03F 2200/294

(57) ABSTRACT

An improved low-dropout (LDO) voltage regulator circuit for RF circuits required to operate using more than one power supply voltage level. An LDO regulates the voltage applied to such a circuit to a specified low voltage even when switched to a power supply having a higher voltage, allowing the circuit to be designed for the lowest available voltage source. When applied to LNAs, preferred embodiments of the invention beneficially re-use several circuit elements as part of the LDO circuitry, allowing an LDO per LNA to be achieved with little or no increase in integrated circuit die area. Some embodiments include an active pull-down circuit to reduce the problem of negative load steps that may cause the LDO output to overshoot and generate an undesirably high voltage spike on its output voltage.

### BACKGROUND

### (1) Technical Field

The invention relates to electronic circuits, and more particularly to radio frequency (RF) circuits such as amplifier circuits and/or RF switches.

### (2) Background

Many modern electronic systems include RF receivers; examples include cellular telephones, personal computers, tablet computers, wireless network components, televisions, cable system “set top” boxes, and radar systems. Many RF receivers are paired with RF transmitters in the form of transceivers, which often are quite complex two-way radios. In some cases, RF transceivers are capable of transmitting and receiving across multiple frequencies in multiple bands.

Amplifiers are a common component in RF transmitters, receivers, and transceivers, and are frequently used for power amplification of transmitted RF signals and for low-noise amplification of received RF signals. RF switches are also common components is such devices, particularly for devices that handle multiple frequency ranges. For many RF systems, particularly those requiring low power and/or portability (e.g., cellular telephones, WiFi-connected computers, cameras, and other devices), it has become common to use complementary metal-oxide semiconductor (CMOS) fabrication technology to create low cost, low power integrated circuits (ICs) based primarily on field-effect transistors (FETs). CMOS FET devices may be fabricated using bulk CMOS, silicon-on-insulator (SOI) CMOS, and silicon-on-sapphire (SOS) processes (SOS being a type of SOI fabrication technology).

Receiving an RF signal in many environments requires a high quality low-noise amplifier (LNA) as part of an RF “front end” (RFFE) receiver or transceiver chain of circuits. Important desired characteristics of an LNA are high gain with low noise, a wide bandwidth, good linearity, and good input and output impedance matching. Device reliability and low power are also important characteristics, especially for portable devices. However, in general, all of these factors cannot be optimized simultaneously, and typically there are tradeoffs between these characteristics when designing an LNA.

In an increasing number of RF-based applications, such as hand-held devices incorporating RF receivers or transceivers, it is useful to support multiple voltage supplies for powering RFFE circuitry, particularly LNAs and RF switches. For example, it may be useful to support different battery types and/or mains-connected transformers having different DC output voltages, thus providing more power supply choices for both designers and end-users of such products. However, designing LNAs and/or RF switches to directly support two or more voltages means optimal performance at one voltage range, but sub-optimal performance at the other voltage ranges. For instance, designing an LNA for a high voltage range (e.g., by using thick-oxide FET devices) means linearity is poor at a lower voltage range. Conversely, designing for a low voltage range (e.g., by using thin-oxide FET devices) means reliability is poor at higher voltage ranges (resulting in higher device failure rates) and/or power supply current (I_{DD}) is higher (resulting in higher power consumption and thus shorter battery life for hand-held products).

Accordingly, there is a need for RF circuit designs that support multiple voltage ranges with little or no impact on RF performance. The present invention addresses this need.

### SUMMARY

Embodiments of the present invention add a low-dropout (LDO) voltage regulator circuit to an LNA or other RF circuit required to operate using more than one power supply voltage level. Each LDO regulates the voltage applied to such circuits to a specified low voltage value even when switched to a power supply having a higher voltage, allowing the coupled RF circuits to be designed for the lowest voltage range available among multiple power supplies. Accordingly, each RF circuit can be optimized for the low voltage value produced by an associated LDO, thereby improving circuit reliability while maintaining high linearity and low power consumption as well as obtaining other benefits.

When applied to LNAs, preferred embodiments of the invention beneficially re-use several circuit elements (e.g., a P-type FET cutoff switch and an RF bypass capacitor) as part of the LDO circuitry. By doing so, implementing an LDO per LNA can be achieved with little or no increase in integrated circuit (IC) die area.

Preferred embodiments of the invention also beneficially take advantage of the presence of “fast charge” (FC) pulse signals generally available in some LNA IC designs to rapidly switch between the current requirements of various gain modes. Since many LNAs require (or have, as a practical matter) a gain/bias switching time and a fast turn-on time, using an FC pulse helps an LDO react faster to transition events but still be stable at normal operating conditions while avoiding large overshoots.

Some embodiments include extra circuit elements to reduce the problem of negative load steps. Negative load steps may cause the output of an LDO to overshoot and thus generate an undesirably high voltage spike at its output. Such voltage spikes, particularly over time, detrimentally affect LNA reliability. Some embodiments of the present invention include an active pull-down circuit to mitigate the negative load step problem.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1 is a block diagram of an example dual-LNA circuit capable of supporting multiple voltage sources.

FIG. 2 is a schematic diagram of an example LDO-LNA circuit capable of supporting multiple voltage sources, showing details of one embodiment of the LDO circuitry.

FIG. 3A is a graph showing a negative change in load current as a function of time for an example LDO.

FIG. 3B is a graph showing LDO output voltage V_{REG} as a function of time for the example LDO of FIG. 3A.

FIG. 4A is a block diagram of one embodiment of circuitry that may be employed to generate the FCOS pulse used to trigger the active pull-down circuit of FIG. 2.

FIGS. 4B-4D are graphs of the voltages at various nodes for the circuit of FIG. 4A as a function of time.

FIG. 5 is a schematic diagram of one embodiment of the pulse shaping circuit shown in FIG. 2.

FIG. 6 is a top plan view of a substrate that may be, for example, a printed circuit board or chip module substrate (e.g., a thin-film tile).

FIG. 7 illustrates a prior art wireless communication environment comprising different wireless communication systems, and which may include one or more mobile wireless devices.

FIG. 8 is a block diagram of a transceiver that might be used in a wireless device, such as a cellular telephone, and which may beneficially incorporate an embodiment of the present invention for improved performance.

FIG. 9 is a process flow chart showing one method for providing a regulated low-voltage power source for RF circuitry.

Like reference numbers and designations in the various drawings indicate like elements unless the context requires otherwise.

### DETAILED DESCRIPTION

Embodiments of the present invention add a low-dropout (LDO) voltage regulator circuit to an LNA or other RF circuit required to operate using more than one power supply voltage level. Each LDO regulates the voltage applied to such circuits to a specified low voltage value even when switched to a power supply having a higher voltage, allowing the RF circuits to be designed for the lowest voltage range available among multiple power supplies. Accordingly, each RF circuit can be optimized for the low voltage value produced by an associated LDO, thereby improving circuit reliability while maintaining high linearity and low power consumption as well as obtaining other benefits.

For purposes of describing the invention, a dual-LNA circuit will be used as one example embodiment of the invention. However, it should be understood that the inventive concepts may be applied to RF circuits that need to operate in conjunction with multiple power supply voltage levels, including power amplifiers and RF switches.

When applied to LNAs, preferred embodiments of the invention beneficially re-use several circuit elements (e.g., a P-type FET cutoff switch and an RF bypass capacitor) as part of the LDO circuitry. By doing so, implementing an LDO per LNA can be achieved with little or no increase in integrated circuit (IC) die area.

Preferred embodiments of the invention also beneficially take advantage of the presence of “fast charge” (FC) pulse signals generally available in some LNA IC designs to rapidly switch between the current requirements of various gain modes (e.g., gain mode G0=15 mA to gain mode G11=10 μA). Since many LNAs require (or have, as a practical matter) a gain/bias switching time and a fast turn-on time (e.g., around 1 μs), using an FC pulse helps an LDO react faster to transition events but still be stable at normal operating conditions while avoiding large overshoots.

Some embodiments include extra circuit elements to reduce the problem of negative load steps. Negative load steps can occur when the load current on an LDO is decreasing, which may cause the LDO to overshoot its normal output value and generate an undesirably high voltage spike at its output. Such voltage spikes, particularly over time, detrimentally affect LNA reliability. Many conventional LDO designs can only passively recover from a negative load step by discharging the output capacitor of the LDO through passive circuit paths. Some conventional LDO designs that try to deal with negative load step overshoot use complicated additional LDO circuitry. In contrast, some embodiments of the present invention include an active pull-down circuit to mitigate the negative load step problem. The active pull-down circuit includes a proper system level control signal and can be implemented very simply with little added overhead to the LDO design.

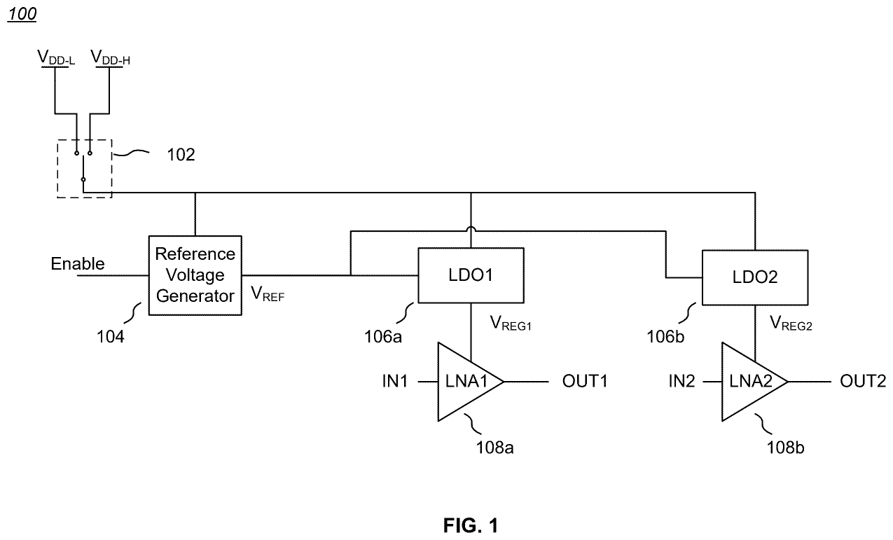

FIG. 1 is a block diagram of an example dual-LNA circuit 100 capable of supporting multiple voltage sources. A switch 102 can selectively couple a low voltage supply V_{DD-L} (e.g., 1.08V) or a high voltage supply V_{DD-H} (e.g., 2.1V) to a reference voltage generator 104, a first LDO1 106a, and a second LDO2 106b. The state of the switch 102 would typically be selected by a command signal from control circuitry (not shown) within an RF-based device. In some embodiments, the switch 102 is not needed, such as when power to an LNA circuit is provided by a battery and the voltage of the power supply is dependent on the attached battery type and voltage (e.g., 1.5V alkaline batteries versus 2.1V lead-acid batteries), or when power is supplied by a mains-connected transformer or alternatively by a battery.

The reference voltage generator 104 generates a reference voltage V_{REF} (e.g., 0.8V). The reference voltage generator 104 may be, for example, a bandgap voltage reference circuit. As is known, a bandgap voltage reference circuit produces an almost constant voltage corresponding to a particular semiconductor's theoretical band gap, with very little fluctuation from variations of power supply, electrical load, time, and/or temperature.

The reference voltage V_{REF} is supplied to LDO1 106a and LDO2 106b, each of which generates a respective regulated voltage V_{REG1}, V_{REG2} (which need not be-but may be-the same voltage). The regulated voltages V_{REG1} and V_{REG2} may be designed, for example, to be in the range of about 1.05V to about 1.32V, and are lower than the output of the high voltage supply V_{DD-H}. The regulated voltages V_{REG1}, V_{REG2} are applied to respective LNA circuits, LNA1 108a and LNA2 108b, which are typically designed to provide optimum performance at the values of the regulated voltages V_{REG1} and V_{REG2}. Each LNA1 108a, LNA2 108b includes a respective input IN1, IN2 and output OUT1, OUT2.

Regardless of whether the low voltage supply V_{DD-L} or the high voltage supply V_{DD-H} is connected to the reference voltage generator 104, LDO1 106a, and LDO2 106b, the regulated voltages V_{REG1}, V_{REG2} remain at an essentially constant low voltage at steady-state current loads.

As should be appreciated, the example dual-LNA circuit 100 can be extended to include more than two LNAs, each with a corresponding LDO. One advantage of having one LDO per LNA—that is, distributed LDOs—is improved isolation between LNAs. Another advantage of distributed LDOs is the ability to re-use existing per-LNA circuit elements as part of the LDO circuitry, in needing very little IC die area for the remaining LDO circuitry (especially compared to using one LDO with larger capacitor and transistor components to supply a regulated voltage to multiple LNAs). However, in alternative embodiments, one LDO may be configured to supply a regulated voltage to more than one LNA. For example, in some embodiments, LDO1 106a may provide V_{REG1} to both LNA1 108a and LNA2 108b, allowing LDO2 106b to be omitted or repurposed.

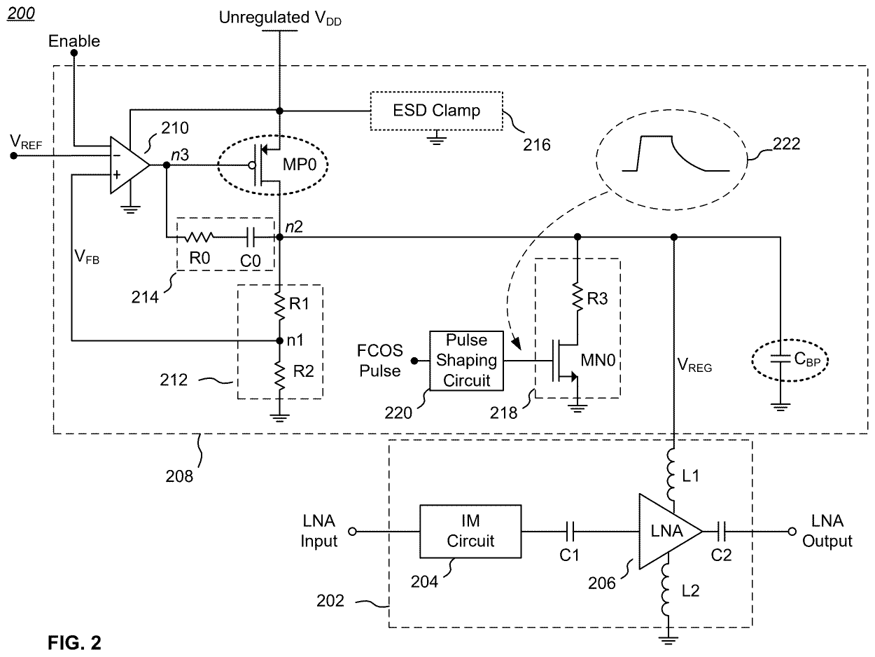

FIG. 2 is a schematic diagram of an example LDO-LNA circuit 200 capable of supporting multiple voltage sources, showing details of one embodiment of the LDO circuitry. The LNA circuitry 202 (within the dashed box) includes an LNA Input (e.g., for receiving an RF signal) coupled to an impedance matching (IM) circuit 204 (which may be, for example, an off-die inductor). The IM circuit 204 is coupled through a DC-blocking capacitor C1 to the input of an LNA 206. An amplified signal from the LNA 206 passes through a DC-blocking capacitor C2 to an LNA Output. Again, while an LNA is used for illustration, the invention may be used in conjunction with power amplifiers, RF switches, and other RF circuits.

In the illustrated example, the LNA 206 is coupled between (1) a load inductor L1 and (2) a degeneration inductor L2 coupled to a reference potential (e.g., circuit ground). As should be appreciated, more sophisticated load and/or degeneration circuits may be used, including circuits with switchable or adjustable inductor values and/or added fixed or adjustable R, C, and/or L components for filtering and/or impedance matching.

In a conventional LNA circuit, power to the LNA 206 would be provided by an unregulated DC voltage source V_{DD} coupled through a transistor MP0 and the inductor L1. The transistor MP0 would typically be a P-type FET (PFET) used as a power cutoff switch to reduce current leakage when the LNA 206 is in a standby mode. In addition, an RF decoupling or bypass capacitor C_{BP} would typically be coupled from a reference potential to a node between the transistor MP0 and the inductor L1 to filter AC signals out of the voltage V_{DD}.

The voltage regulation circuitry for the inventive LDO 208 (within the dashed box) beneficially re-uses two components of a conventional LNA circuit; the dottted ovals indicate the re-used components. The transistor MP0 is re-used as a pass transistor to regulate V_{DD} down to V_{REG} while maintaining its cutoff function. The capacitor C_{BP} is re-used as an output capacitor for the LDO 208 while maintaining its AC bypass function. Thus, capacitor C_{BP} filters noise from the output of the LDO 208 and provides a charge reservoir for smoothing the output of the LDO 208. Since transistor MP0 and capacitor C_{BP} tend to consume a substantial amount of IC area (e.g., about 7% of total area for one example embodiment of an LNA), such re-use has economic benefits.

The voltage regulation circuitry of the LDO 208 further includes a differential error amplifier 210 having a first input coupled to a stable reference voltage V_{REF} (e.g., a bandgap reference) and an output connected to the gate of transistor MP0. In the illustrated example, the error amplifier 210 is powered by V_{DD} (the voltage source to be regulated) and is connected to a reference potential (e.g., circuit ground). Transistor MP0 is connected between V_{DD} and a voltage divider 212, which in this example comprise resistors R1 and R2 connected in series between transistor MP0 and the reference potential. A feedback voltage V_{FB} is provided from node n1 between resistors R1 and R2 to a second input of the error amplifier 210. The error amplifier 210 may include an Enable input line to allow the error amplifier 210 to control the pass or block state of transistor MP0 and thus preserve the power cutoff switch function of transistor MP0.

Some embodiments of the voltage regulation circuitry may include a frequency compensation circuit 214 to stabilize the control loop of the LDO 208. In the illustrated example, the frequency compensation circuit 214 comprises a capacitor C0 and resistor R0 coupled in series between the output of the LDO 208 (node n2) and the output of the error amplifier 210 (node n3). Different embodiments may use different circuitry for the frequency compensation circuit 214.

In operation, the input to the error amplifier 210 from node n1 comprises a fraction of the output from transistor MP0 (determined by the resistor ratio of R1 to R2), which is compared against the reference voltage V_{REF}. If the output voltage of transistor MP0 at node n2 rises too high relative to the reference voltage V_{REF}, the output of the error amplifier 210 changes the drive bias to the gate of transistor MP0 so as to maintain an essentially constant output voltage V_{REG} at a particular load current.

It should be appreciated that the illustrated LDO 208 may be more complex. For example, in some embodiments, an electrostatic discharge (ESD) clamp 216 coupled to the V_{DD} input may be included. As a further example, the LDO 208 may include a driver transistor connected between the output of the error amplifier 210 and the gate of transistor MP0.

An additional design aspect to consider is dealing with load steps—changes in the current load required by the LNA 206, such as when gain modes change. A positive load-step (i.e., load current increasing in value) may cause the V_{REG} output of the LDO 208 to undershoot until the LDO control loop can respond and decrease the gate voltage of transistor MP0. However, for some applications, undershoot does not present a significant problem (there is generally no voltage stress on the LNA 206) and the LDO 208 circuit need not be modified to deal with that condition.

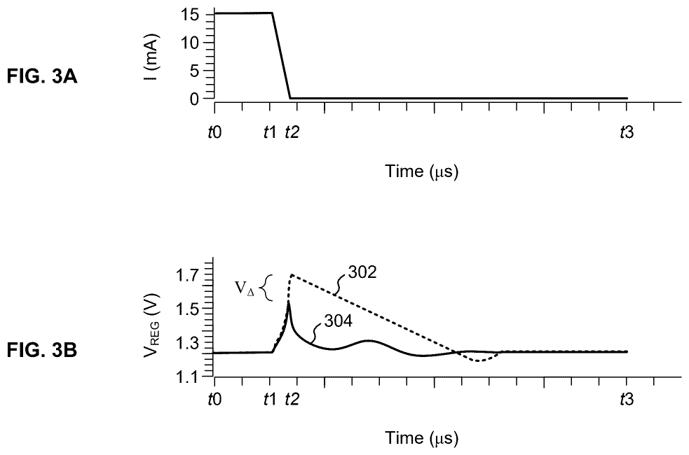

However, with negative load steps (i.e., load current decreasing in value), the LDO output may cause the V_{REG} output of the LDO 208 to overshoot until the LDO control loop can respond and increase the gate voltage of transistor MP0 to turn the pass transistor MP0 OFF for a time. For example, FIG. 3A is a graph showing a negative change in load current as a function of time for an example LDO 208. FIG. 3B is a graph showing LDO output voltage V_{REG} as a function of time for the example LDO 208 of FIG. 3A. As illustrated in FIG. 3A, the load current decreases from about 15 mA to about 1 μA between time t1 and time t2. That negative load step results in a voltage overshoot in V_{REG}, shown by graph line 302 in FIG. 3B. An overshoot that is too large and/or is frequently repeated can cause voltage stress to the LNA 206, resulting in decreased reliability.

A conventional LDO can only passively recover from a negative load step, meaning that the LDO control loop needs to turn the pass transistor MP0 OFF for a time until the LDO output voltage V_{REG} recovers by bleeding charge off of the output capacitor C_{BP} with whatever current is pulled from the output node n2 by the LNA 206 and the voltage divider 212.

To mitigate the negative load step overshoot problem of a conventional LDO, embodiments of the present invention utilize an active pull-down circuit as part of the improved LDO 208. For example, referring back to FIG. 2, an active pull-down circuit 218 may comprise a N-type FET (NFET) pull-down transistor MN0 and a resistor R3 coupled in a shunt configuration between the output node n2 of the LDO 208 and the reference potential (note that the order of transistor MN0 and resistor R3 may be reversed). The gate of transistor MN0 is coupled to the output of a pulse shaping circuit 220, which receives a Fast Charge One-Shot (FCOS) pulse as an input and generates an output pulse having a gradual or “soft” falling edge, similar to that shown in the dashed oval 222 in FIG. 2.

In operation in a pull-down mode, when the FCOS pulse is applied to the pulse shaping circuit 220, transistor MN0 is activated (turns ON to be conducting) and rapidly drains excess charge from the output capacitor C_{BP} through resistor R3 to the reference potential, thereby lowering the value of V_{REG}. The component values for pull-down transistor MN0 and a resistor R3 are preferably selected so that the pull-down current is weak enough that transistor MP0 can take over and prevent the output V_{REG} from being pulled too low. Resistor R3 determines the duration of any overshoot, but preferably should not be sized so high in value as to cause a problem with positive load steps. In one example embodiment, R3 was sized in the range of 150 kΩ to about 250 kΩ. Since transistor MN0 does not source or sink any significant current, it can be small, thus saving IC die space. As should be clear, various other triggerable discharge circuits may be used for the active pull-down circuit 218.

Referring back to FIG. 3B, graph line 304 shows the results of activating transistor MN0: the difference V_{Δ} and duration of the voltage overshoot is significantly less than the voltage overshoot in V_{REG} (graph line 302) of a conventional LDO. While there is still a little overshoot with the active pull-down circuit 218, the magnitude and duration is greatly reduced, removing over-voltage stress concerns, and the active pull-down circuit 218 gets the LDO output V_{REG} close to a final value much quicker than a passive pull-down solution.

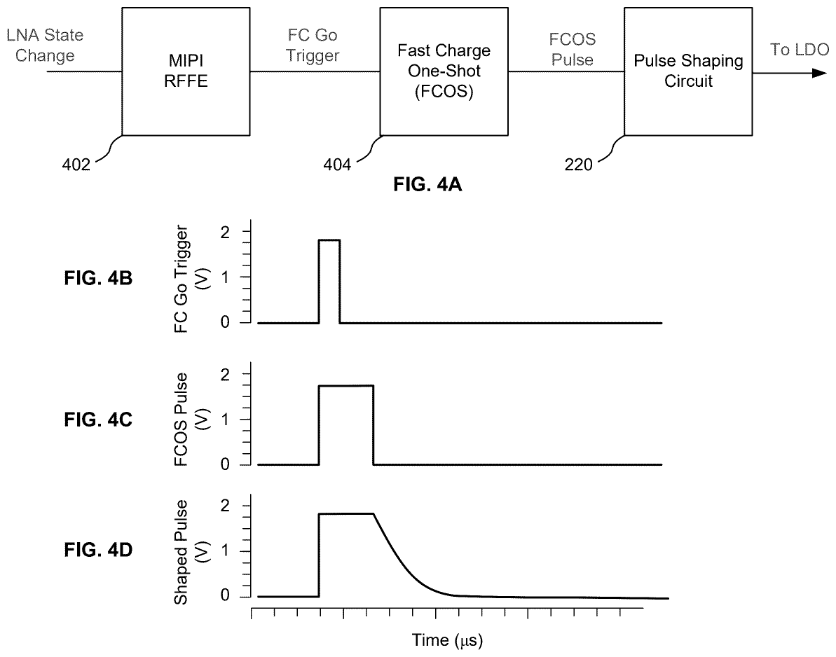

FIG. 4A is a block diagram of one embodiment of circuitry that may be employed to generate the FCOS pulse used to trigger the active pull-down circuit 218 of FIG. 2. FIGS. 4B-4D are graphs of the voltages at various nodes for the circuit of FIG. 4A as a function of time (the time axis is the same for FIGS. 4B-4D and thus shown only once). In the illustrated example, a Mobile Industry Processor Interface (MIPI) RFFE block 402 receives an LNA State Change control signal from a controller (not shown) sent, for example, when there is gain/bias/band mode switching. As is known, the MIPI RFFE block 402 generates (among other signals) an FC Go Trigger, such as is illustrated in FIG. 4B. The rising edge of the FC Go Trigger is aligned to the end of the LNA State Change control signal. The FC Go Trigger may have any useful or needed duration (for example, as short as about 4-5 ns and as long as the controller idle time). Notably, LNA state changes can cause a negative load step.

The FC Go Trigger is applied to a Fast Charge One-Shot circuit 404, which is triggered by the rising edge of the FC Go Trigger signal and outputs a FCOS Pulse with a rising edge aligned to the rising edge of the FC GO Trigger and of a controlled duration, as shown in FIG. 4C. The FCOS Pulse may have a designed duration, for example, of about 500 ns. Of note, a number of existing LNA ICs already include a FCOS circuit 404 for other purposes, hence no additional circuitry is needed to generate the FCOS Pulse when the improved LDO 208 is added to such ICs.

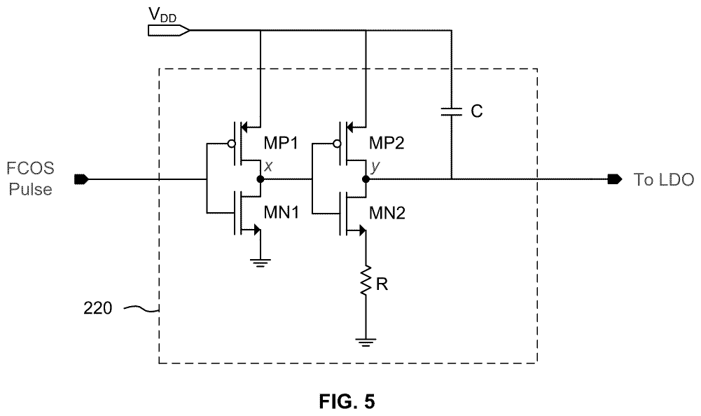

The FCOS pulse is applied to the pulse shaping circuit 220 shown in FIG. 2, which generates an output pulse similar to that shown in FIG. 4D. Of note, the pulse shaping circuit 220 generates a “soft” falling edge to avoid another “negative going” step response. The pulse shaping circuit 220 may be implemented as a variable pulse width generator. For example, FIG. 5 is a schematic diagram of one embodiment of the pulse shaping circuit 220 shown in FIG. 2. A FCOS Pulse from the FCOS circuit 404 of FIG. 4A is applied to the gates of a first inverter comprising a PFET MP1 and an NFET MN1 coupled in series between V_{DD} and the reference potential. An output node x between MP1 and MN1 is applied to the gates of a second inverter comprising a PFET MP2 and an NFET MN2 coupled in series between V_{DD} and resistor R, which in turn is coupled to the reference potential. The resistor R may be implemented as a series of resistors in some embodiments. A capacitor C is coupled between V_{DD} and an output node y between MP2 and MN2, and provides a soft-falling edge to the output of the pulse shaping circuit 220.

In operation, when the FCOS pulse goes from low (e.g., 0V) to high (e.g., to about V_{DD} MP2 conducts and MN2 blocks. The result is that the output node y essentially instantly goes from low to about VDD (less the voltage drop across MP2) and capacitor C is charged to VDD. When the FCOS pulse goes low (e.g., 0V), MP2 blocks and MN2 conducts. The result is that the output node y more slowly returns to low as capacitor C discharges through resistor R, thus shaping the output to have a soft falling edge. The characteristics of the soft-falling edge may be adjusted by the selection of values for the capacitor C and the resistor R as needed for a particular application. The soft-falling edge pulse generated at node y is coupled to the gate of pull-down transistor MN0, as shown in FIG. 2 and described above.

Embodiments of the present invention allow RF circuits to be designed for the lowest voltage range available among multiple power sources. Accordingly, each LNA or RF circuit can be optimized for the low regulated voltage value produced by an associated LDO, thereby improving circuit reliability while maintaining high linearity and low power consumption. Re-use of several LNA circuit elements as part of the LDO circuitry allows implementation of an LDO per LNA with little or no increase in IC die area. Use of “fast charge” (FC) pulse signals and an active pull-down circuit within an LDO allows rapid switching between various current requirements and mitigates the negative load step problem.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

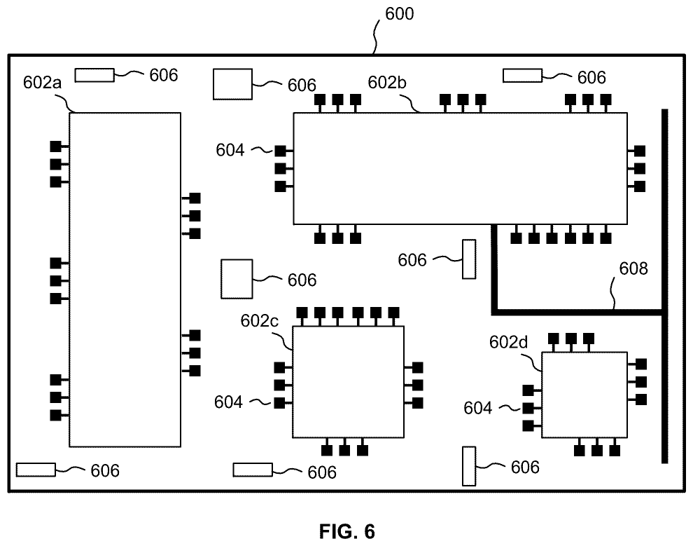

As one example of further integration of embodiments of the present invention with other components, FIG. 6 is a top plan view of a substrate 600 that may be, for example, a printed circuit board or chip module substrate (e.g., a thin-film tile). In the illustrated example, the substrate 600 includes multiple ICs 602a-602d having terminal pads 604 which would be interconnected by conductive vias and/or traces on and/or within the substrate 600 or on the opposite (back) surface of the substrate 600 (to avoid clutter, the surface conductive traces are not shown and not all terminal pads are labelled). The ICs 602a-602d may embody, for example, signal switches, active and/or passive filters, amplifiers (including one or more LNAs), and other circuitry. For example, IC 602b may incorporate one or more instances of an RF circuit that utilizes the novel LDO circuit.

The substrate 600 may also include one or more passive devices 606 embedded in, formed on, and/or affixed to the substrate 600. While shown as generic rectangles, the passive devices 606 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 600 to other passive devices 606 and/or the individual ICs 602a-602d.

The front or back surface of the substrate 600 may be used as a location for the formation of other structures. For example, one or more antennae may be formed on or affixed to the front or back surface of the substrate 600; one example of a front-surface antenna 608 is shown, coupled to an IC die 602b, which may include RF front-end circuitry. Thus, by including one or more antennae on the substrate 600, a complete radio may be created.

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

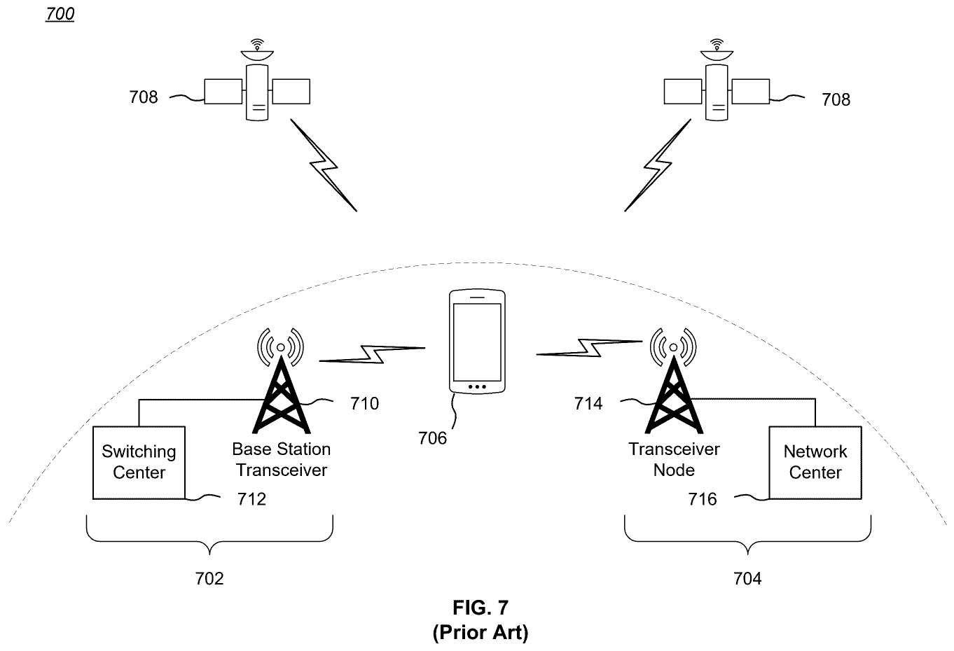

As an example of wireless RF system usage, FIG. 7 illustrates a prior art wireless communication environment 700 comprising different wireless communication systems 702 and 704, and which may include one or more mobile wireless devices 706. A wireless device 706 may be a cellular phone, a wireless-enabled computer or tablet, or some other wireless communication unit or device. A wireless device 706 may also be referred to as a mobile station, user equipment, an access terminal, or some other terminology known in the telecommunications industry.

A wireless device 706 may be capable of communicating with multiple wireless communication systems 702, 704 using one or more of telecommunication protocols such as the protocols noted above. A wireless device 706 also may be capable of communicating with one or more satellites 708, such as navigation satellites (e.g., GPS) and/or telecommunication satellites. The wireless device 706 may be equipped with multiple antennas, externally and/or internally, for operation on different frequencies and/or to provide diversity against deleterious path effects such as fading and multi-path interference.

The wireless communication system 702 may be, for example, a CDMA-based system that includes one or more base station transceivers (BSTs) 710 and at least one switching center (SC) 712. Each BST 710 provides over-the-air RF communication for wireless devices 706 within its coverage area. The SC 712 couples to one or more BSTs 710 in the wireless system 702 and provides coordination and control for those BSTs 710.

The wireless communication system 704 may be, for example, a TDMA-based system that includes one or more transceiver nodes 714 and a network center (NC) 716. Each transceiver node 714 provides over-the-air RF communication for wireless devices 706 within its coverage area. The NC 716 couples to one or more transceiver nodes 714 in the wireless system 704 and provides coordination and control for those transceiver nodes 714.

In general, each BST 710 and transceiver node 714 is a fixed station that provides communication coverage for wireless devices 706, and may also be referred to as base stations or some other terminology known in the telecommunications industry. The SC 712 and the NC 716 are network entities that provide coordination and control for the base stations and may also be referred to by other terminologies known in the telecommunications industry.

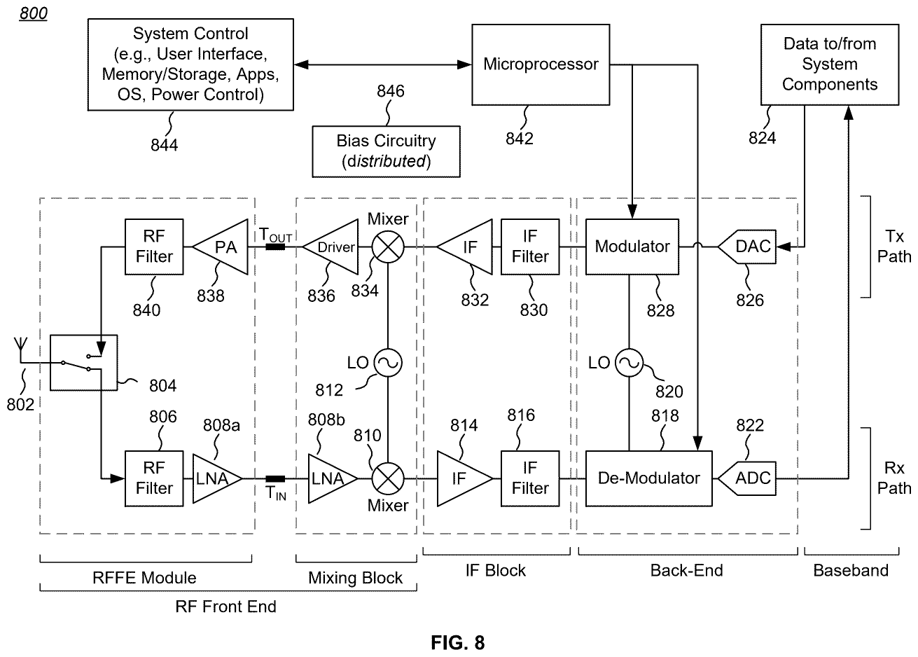

An important aspect of any wireless system, including the systems shown in FIG. 7, is in the details of how the component elements of the system perform. FIG. 8 is a block diagram of a transceiver 800 that might be used in a wireless device, such as a cellular telephone, and which may beneficially incorporate an embodiment of the present invention for improved performance. As illustrated, the transceiver 800 includes a mix of RF analog circuitry for directly conveying and/or transforming signals on an RF signal path, non-RF analog circuity for operational needs outside of the RF signal path (e.g., for bias voltages and switching signals), and digital circuitry for control and user interface requirements. In this example, a receiver path Rx includes RF Front End (RFFE), Intermediate Frequency (IF) Block, Back-End, and Baseband sections (noting that in some implementations, the differentiation between sections may be different). The various illustrated sections and circuit elements may be embodied in one die or multiple IC dies. For example, the RF Front End in the illustrated example may include an RFFE module and a Mixing Block, which may be embodied in (or as part of) different IC dies or modules. The different dies and/or modules may be coupled by transmission lines TIN and TOUT (e.g., microstrips, co-planar waveguides, or an equivalent structure or circuit), either or both of which may have, for example, a 50 Ω impedance.

The receiver path Rx receives over-the-air RF signals through at least one antenna 802 and a switching unit 804, which may be implemented with active switching devices (e.g., field effect transistors or FETs) and/or with passive devices that implement frequency-domain multiplexing, such as a diplexer or duplexer. An RF filter 806 passes desired received RF signals to at least one low noise amplifier (LNA) 808a, the output of which is coupled from the RFFE Module to at least one LNA 808b in the Mixing Block (through transmission line TIN in this example). The LNA(s) 808b may provide buffering, input matching, and reverse isolation. In some embodiments, the LNA(s) 808a and 808b may be a single LNA.

The output of the LNA(s) 808b is combined in a corresponding mixer 810 with the output of a first local oscillator LO 812 to produce an IF signal. The IF signal may be amplified by an IF amplifier 814 and subjected to an IF filter 816 before being applied to a demodulator 818, which may be coupled to a second local oscillator LO 820. The demodulated output of the demodulator 818 is transformed to a digital signal by an analog-to-digital converter (ADC) 822 and provided to one or more system circuits 824 (e.g., a video graphics circuit, a sound circuit, memory devices, etc.). The converted digital signal may represent, for example, video or still images, sounds, or symbols, such as text or other characters.

In the illustrated example, a transmitter path Tx includes Baseband, Back-End, IF Block, and RF Front End sections (again, in some implementations, the differentiation between sections may be different). Digital data from one or more system circuits 824 is transformed to an analog signal by a digital-to-analog converter (DAC) 826, the output of which is applied to a modulator 828, which also may be coupled to the second local oscillator LO 820. The modulated output of the modulator 828 may be subjected to an IF filter 830 before being amplified by an IF amplifier 832. The output of the IF amplifier 832 is then combined in a mixer 834 with the output of the first local oscillator LO 812 to produce an RF signal. The RF signal may be amplified by a driver 836, the output of which is coupled to a power amplifier (PA) 838 (through transmission line TOUT in this example). The amplified RF signal may be coupled to an RF filter 840, the output of which is coupled to at least one antenna 802 through the switching unit 804.

The operation of the transceiver 800 is controlled by a microprocessor 842 in known fashion, which interacts with system control components or circuits 844 (e.g., user interfaces, memory/storage devices, application programs, operating system software, power control, etc.). In addition, the transceiver 800 will generally include other circuitry, such as bias circuitry 846 (which may be distributed throughout the transceiver 800 in proximity to transistor devices), electro-static discharge (ESD) protection circuits, testing circuits (not shown), factory programming interfaces (not shown), etc.

In modern transceivers, there are often more than one receiver path Rx and transmitter path Tx, for example, to accommodate multiple frequencies and/or signaling modalities. Further, as should be apparent to one of ordinary skill in the art, some components and/or circuits of the transceiver 800 may be positioned in a different order (e.g., filters) or omitted. Other components and/or circuits can be (and often are) added, such as (by way of example only) additional filters, impedance matching networks, variable phase shifters/attenuators, power dividers, etc.

As a person of ordinary skill in the art will understand, a system architecture is beneficially impacted by the current invention in critical ways, including high linearity, higher reliability, lower power consumption, and improved battery life. In order to comply with a number of system standards or customer requirements, the current invention is therefore critical to the overall solution shown in FIGS. 2 and 8.

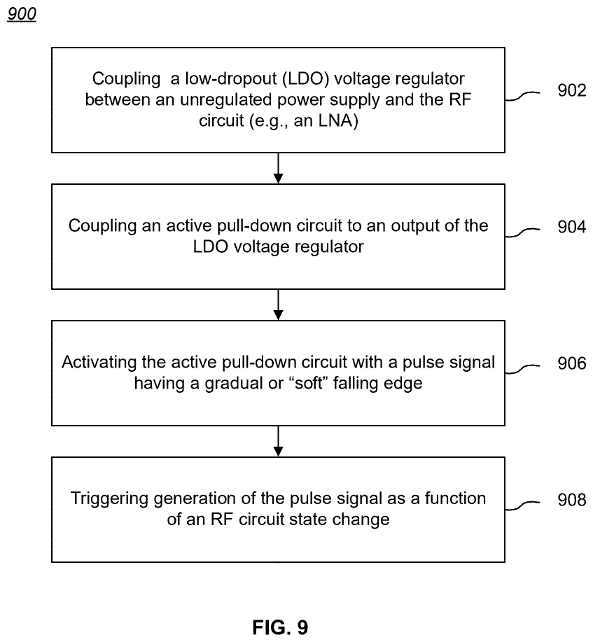

Another aspect of the invention includes methods for providing a regulated low-voltage power source for RF circuitry while achieving higher reliability, maintaining high linearity, and achieving low power consumption. For example, FIG. 9 is a process flow chart 900 showing one method for providing a regulated low-voltage power source for an RF circuit. The method includes: providing a low-dropout (LDO) voltage regulator per RF circuit (e.g., an LNA) (Block 902); coupling an active pull-down circuit to an output of the LDO voltage regulator (Block 904); activating the active pull-down circuit with a pulse signal having a gradual or “soft” falling edge (Block 906); and triggering generation of the pulse signal as a function of an RF circuit state change (Block 908).

Additional aspects of the above method may include one or more of the following: wherein the active pull-down circuit comprises a pull-down transistor and a resistor coupled in a shunt configuration between the output of the LDO voltage regulator and a reference potential; using a single transistor as both a pass-transistor for the LDO voltage regulator and as a power cutoff transistor for the RF circuit; using a single capacitor as both an output capacitor for the LDO voltage regulator and as a bypass or decoupling capacitor for the RF circuit; and/or wherein the RF circuit is an LNA.

The term “MOSFET”, as used in this disclosure, includes any field effect transistor (FET) having an insulated gate whose voltage or charge level determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as bipolar junction transistors (BJTs), BiCMOS, LDMOS, BCD, GaAs HBT, GaN HEMT, GaAs pHEMT, MESFET, InP HBT, InP HEMT, FinFET, GAAFET, and SiC-based device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A low-dropout (LDO) voltage regulator circuit for an RF circuit including:
(a) an input for receiving an unregulated voltage;
(b) an output for providing a regulated voltage;
(c) voltage regulation circuitry coupled to the input and the output and configured to regulate the unregulated voltage to be the regulated voltage;
(d) an active pull-down circuit coupled to the output of the LDO voltage regulator and configured to be coupled to a reference potential, wherein the active pull-down circuit is activated by a pulse signal having a soft falling edge.

2. The LDO voltage regulator circuit of claim 1, wherein the pulse signal is generated as a function of an RF circuit state change.

3. The LDO voltage regulator circuit of claim 1, wherein the voltage regulation circuitry includes a transistor, coupled between the input and the output, and functional as both a pass-transistor for the LDO voltage regulator circuit and as a power cutoff transistor for the RF circuit.

4. The LDO voltage regulator circuit of claim 1, wherein the voltage regulation circuitry includes a capacitor, coupled to the output, and functional as both an output capacitor for the LDO voltage regulator circuit and as a decoupling capacitor for the RF circuit.

5. The LDO voltage regulator circuit of claim 1, wherein the RF circuit is a low-noise amplifier circuit.

6. The LDO voltage regulator circuit of claim 1, wherein the active pull-down circuit includes a resistor and a transistor coupled in series between the output and the reference potential.

7. The LDO voltage regulator circuit of claim 6, wherein the transistor of the active pull-down circuit is coupled to a pulse shaping circuit configured to generate the pulse signal.

8. The LDO voltage regulator circuit of claim 7, wherein pulse shaping circuit generates the pulse signal in response to an RF circuit state change.

9. The LDO voltage regulator circuit of claim 1, further including an electrostatic discharge clamp coupled to the input and configured to be coupled to the reference potential.

10. The LDO voltage regulator circuit of claim 1, wherein the voltage regulation circuitry includes a frequency compensation circuit to stabilize a control loop of the LDO voltage regulator circuit.

11. An electronic circuit including:
(a) an amplifier including a power input; and
(b) a low-dropout (LDO) voltage regulator circuit including:
(1) an input for receiving an unregulated voltage, and
(2) an output configured to provide a regulated voltage to the power input of the amplifier;
(3) voltage regulation circuitry coupled to the input and the output and configured to regulate the unregulated voltage to be the regulated voltage;
(4) an active pull-down circuit coupled to the output of the LDO voltage regulator and configured to be coupled to a reference potential, wherein the active pull-down circuit is activated by a pulse signal having a soft falling edge.

12. The electronic circuit of claim 11, wherein the pulse signal is generated as a function of a state change of the electronic circuit.

13. The electronic circuit of claim 11, wherein the voltage regulation circuitry includes a transistor, coupled between the input and the output, and functional as both a pass-transistor for the LDO voltage regulator circuit and as a power cutoff transistor for the amplifier.

14. The electronic circuit of claim 11, wherein the voltage regulation circuitry includes a capacitor, coupled to the output, and functional as both an output capacitor for the LDO voltage regulator circuit and as a decoupling capacitor for the amplifier.

15. The electronic circuit of claim 11, wherein the amplifier is a low-noise amplifier.

16. The electronic circuit of claim 11, wherein the active pull-down circuit includes a resistor and a transistor coupled in series between the output and the reference potential.

17. The electronic circuit of claim 16, wherein the transistor of the active pull-down circuit is coupled to a pulse shaping circuit configured to generate the pulse signal.

18. The electronic circuit of claim 17, wherein pulse shaping circuit generates the pulse signal in response to a state change of the electronic circuit.

19. The LDO voltage regulator circuit of claim 11, further including an electrostatic discharge clamp coupled to the input and configured to be coupled to the reference potential.

20. The LDO voltage regulator circuit of claim 11, wherein the voltage regulation circuitry includes a frequency compensation circuit to stabilize a control loop of the LDO voltage regulator circuit.

21.-25. (canceled)
